(19) United States
(12) Patent Application Publication
(10) Pub. No.: US 2004/0191413 A1
(43) Pub. Date: Sep. 30, 2004

(54) Reactor for thin film deposition and method for depositing thin film on wafer using the reactor

(76) Inventors: Young Hoon Park, Pyungtaek-city (KR); Keun Jae Yoo, Pyungtaek-city (KR); Hong Joo Lim, Pyungtaek-city (KR); Sang Jin Lee, Pyungtaek-city (KR); Ik Haeng Lee, Pyungtaek-city (KR); Sang Kyu Lee, Pyungtaek-city (KR); Hyun Soo Kyung, Pyungtaek-city (KR); Jang Ho Bae, Pyungtaek-city (KR)

Correspondence Address: CANTOR COLBURN, LLP, 55 GRIFFIN ROAD SOUTH, BLOOMFIELD, CT, 06002

(21) Appl. No.: 10/484,047

(22) PCT Filed: Jul. 16, 2002
(86) PCT No.: PCT/KR02/01342

(30) Foreign Application Priority Data
Jul. 19, 2001 (KR) 2001/43496

(51) Int. Cl. C23C 16/00

(52) U.S. Cl. 427/255.28; 427/255.23; 427/248.1; 118/723 R; 118/723 E

(57) ABSTRACT

A reactor for thin film deposition and a thin film deposition method using the reactor are provided. The reactor includes: a reactor block which receives a wafer transferred through a wafer transfer slit; a wafer block which is installed in the reactor block to receive the wafer thereon; a top plate disposed to cover the reactor block; a shower head which is mounted on the bottom of the top plate and diffuses gas toward the wafer; and an exhaust unit which exhausts the gas from the reactor block. A first supply pipeline which supplies a first reactant gas and/or an inert gas to the wafer; a second supply pipeline which supplies a second reactant gas and/or an inert gas to the wafer; and a plasma generator which generates plasma between the wafer block and shower head are included. The shower head includes: a first supply path connected to the first supply pipeline; a plurality of first diffuse holes formed in the bottom of the shower head at a constant interval; a first main path formed parallel to the plane of the shower head and connecting the plurality of first diffuse holes and the first supply path; a second supply path connected to the second supply pipeline; a plurality of second diffuse holes formed in the bottom of the shower head at a constant interval as the plurality of the first diffuse holes; and a second main path formed parallel to the plane of the shower head at a different height from the second main path and connecting the plurality of second diffuse holes and the second supply path.

### TECHNICAL FIELD

The present invention relates to a reactor for use in deposition of a thin film on a semiconductor wafer and a method for depositing a thin film using the reactor.

### BACKGROUND ART

A reactor for the deposition of a thin film is an apparatus for forming a predetermined thin film on a wafer accommodated therein by using a variety of kinds of reactant gases flowed therein.

Deposition of high-purity thin films having good electrical properties on a wafer is necessary to form a high-density chip. Recently, efforts have been shifted toward using atomic layer deposition (ALD) from conventional chemical vapor deposition and have increased a demand for efficient ALD processes and equipment in the manufacture of a semiconductor device. This is because the ALD technique can provide an even narrower design rule, which is the trend in developing new technology in the semiconductor field, with high quality and reliability of a deposited thin film.

### DISCLOSURE OF THE INVENTION

It is an object of the present invention to provide an improved reactor for effectively depositing a high-purity, thin film having good electrical characteristics and step coverage on a wafer using a plurality of reactant gases and a method for depositing a thin film using the reactor.

It is another object of the present invention to provide a reactor for depositing a thin film at low temperature by intermittently or continuously generating plasma while feeding and purging a plurality of reactant gases and a method for depositing a thin film using the reactor.

According to an aspect of the present invention, there is provided a reactor for thin film deposition, comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate and diffuses gas toward the wafer; and an exhaust unit which exhausts the gas from the reactor block, the reactor characterized by comprising: a first supply pipeline which supplies a first reactant gas and/or an inert gas to the wafer; and a second supply pipeline which supplies a second reactant gas and/or an inert gas to the wafer, wherein the shower head comprises: a first supply path connected to the first supply pipeline; a plurality of first diffuse holes formed in the bottom of the shower head at a constant interval; a first main path formed parallel to the plane of the shower head and connecting the plurality of first diffuse holes and the first supply path; a second supply path connected to the second supply pipeline; a plurality of second diffuse holes formed in the bottom of the shower head at a constant interval as the plurality of the first diffuse holes; and a second main path formed parallel to the plane of the shower head at a different height from the first main path and connecting the plurality of second diffuse holes and the second supply path.

It is preferable that the first main path and the second main path are formed parallel or perpendicular to each other. The shower head may further comprise a plurality of first sub-paths perpendicularly diverting from the first main path to be in parallel with the plane of the shower head and a plurality of first diffuse paths connecting the plurality of first sub-paths and the plurality of first diffuse holes. The shower head may further comprise a plurality of second sub-paths perpendicularly diverting from the second main path to be in parallel with the plane of the shower head and a plurality of second diffuse paths connecting the plurality of second sub-paths and the plurality of second diffuse holes.

Preferably, the reactor further comprises: a plasma generator which generates plasma between the wafer block and the shower head; and a power road for preventing disturbance due to electromagnetic waves generated from the plasma generator, including a conductive wire electrically connected to the shower head, an insulator surrounding the conductive wire, and a grounded conductor surrounding the insulator.

In the reactor according to the present invention, it is preferable that the first supply pipeline and the first supply path are connected via a first insulating connector, and the second supply pipeline and the second supply path are connected via a second insulating connector.

In another reactor for thin film deposition according to the present invention, comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate and diffuses gas toward the wafer; and an exhaust unit which exhausts the gas from the reactor block, the reactor is characterized by comprising: a first supply pipeline which supplies a first reactant gas and/or an inert gas to the wafer; a second supply pipeline which supplies a second reactant gas and/or an inert gas to the wafer, and a third supply pipeline which supplies a third reactant gas and/or an inert gas to the wafer, wherein the shower head comprises: a first supply path connected to the first supply pipeline; a plurality of first diffuse holes formed in the bottom of the shower head at a constant interval; a first main path formed parallel to the plane of the shower head and connecting the plurality of first diffuse holes and the first supply path; a second supply path connected to the second supply pipeline; a plurality of second diffuse holes formed in the bottom of the shower head at a constant interval as the plurality of the first diffuse holes; a second main path formed parallel to the plane of the shower head at a different height from the first main path and connecting the plurality of second diffuse holes and the second supply path; a third supply path connected to the third supply pipeline; a plurality of third diffuse holes formed in the bottom of the shower head at a constant interval as the plurality of the first and second diffuse holes; and a third main path formed parallel to the plane of the shower head at a different height from the first and second main paths and connecting the plurality of third diffuse holes and the third supply path.

It is preferably that at least two of the first, second, and third main paths are formed parallel or perpendicular to each other. The shower head may further comprise a plurality of first sub-paths perpendicularly diverting from the first main path to be in parallel with the plane of the shower head and a plurality of first diffuse paths connecting the plurality of first sub-paths and the plurality of first diffuse holes. The shower head may further comprise a plurality of second sub-paths perpendicularly diverting from the second main path to be in parallel with the plane of the shower head and a plurality of second diffuse paths connecting the plurality of second sub-paths and the plurality of second diffuse holes. The shower head mat further comprise a plurality of third sub-paths perpendicularly diverting from the third main path to be in parallel with the plane of the shower head and a plurality of third diffuse paths connecting the plurality of third sub-paths and the plurality of third diffuse holes.

Preferably, the reactor for depositing a thin film using three kinds of reactant gases further comprises: a plasma generator which generates plasma between the wafer block and the shower head; and a power road for preventing disturbance due to electromagnetic waves generated from the plasma generator, including a conductive wire electrically connected to the shower head, an insulator surrounding the conductive wire, and a grounded conductor surrounding the insulator. In this reactor, it is preferable that the first supply pipeline and the first supply path are connected via a first insulating connector, the second supply pipeline and the second supply path are connected via a second insulating connector, and the third supply pipeline and the third supply path are connected via a third insulating connector.

According to another aspect of the present invention, there is provided a method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer and a plurality of second diffuse holes for supplying a second reactant gas and/or an inert gas to the wafer; a plasma generator which generates plasma between the wafer block and the shower head; and an exhaust unit which exhausts the gas from the reactor block, the method comprising, while the inert gases are continuously supplied to the wafer through the plurality of first and second diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, and purging the second reactant gas from the reactor. Next, the plasma is generated after feeding the second reactant gas, and the generation of the plasma is stopped after pursing the second reactant gas and before feeding the first reactant gas.

Alternatively, the present invention provides a method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer and a plurality of second diffuse holes for supplying a second reactant gas and/or an inert gas to the wafer; a plasma generator which generates plasma between the wafer block and the shower head; and an exhaust unit which exhausts the gas from the reactor block, the method comprising, while the inert gases are continuously supplied to the wafer through the plurality of first and second diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, and purging the second reactant gas from the reactor. Next, the plasma is continuously generated during the feeding and purging of the first and second reactant gases.

Alternatively, the present invention provides a method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer, a plurality of second diffuse holes for supplying a second reactant gas and/or an inert gas to the wafer, and a plurality of third diffuse holes for supplying a third reactant gas and/or an inert gas to the wafer; a plasma generator which generates plasma between the wafer block and the shower head; and an exhaust unit which exhausts the gas from the reactor block, the method comprising, while the inert gases are continuously supplied to the wafer through the plurality of first, second, and third diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, purging the second reactant gas from the reactor, feeding the third reactant gas into the reactor through the plurality of third diffuse holes in a predetermined amount, and purging the third reactant gas from the reactor. The plasma is generated after feeding each of the second and third reactant gases, and the generation of the plasma is stopped after purging each of the second and third reactant gases and before feeding a next reactant gas.

Alternatively, the present invention provides a method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer, a plurality of second diffuse holes for supplying a second reactant gas and/or an inert gas to the wafer, and a plurality of third diffuse holes for supplying a third reactant gas and/or an inert gas to the wafer; a plasma generator which generates plasma between the wafer block and the shower head; and an exhaust unit which exhausts the gas from the reactor block, the method comprising, while the inert gases are continuously supplied to the wafer through the plurality of first, second, and third diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, purging the second reactant gas from the reactor, feeding the third reactant gas into the reactor through the plurality of third diffuse holes in a predetermined amount, and purging the third reactant gas from the reactor. The plasma is continuously generated during the feeding and purging of the first, second, and third reactant gases.

### BRIEF DESCRIPTION OF THE DRAWINGS

FIG. 1 is an exploded perspective view of a reactor for thin film deposition according to the present invention;

FIG. 2 is a sectional view of a plasma power load of FIG. 1;

FIG. 3 is a sectional view of the reactor of FIG. 1 according to a preferred embodiment of the present invention;

FIG. 4 is a perspective view of the shower head of FIG. 3;

FIG. 5 is a bottom view of the shower head of FIG. 4;

FIG. 6 is a perspective view of the shower head of FIG. 3, showing a first main path connected to a first supply path and a plurality of first diffuse paths;

FIG. 7 is a sectional view taken along line VII-VII′ of FIG. 6;

FIG. 8 is a sectional view of the shower head of FIG. 6;

FIG. 9 is a perspective view of the shower head of FIG. 3, showing a second main path connected to the second supply path and a plurality of second diffuse paths;

FIG. 10 is a sectional view taken along line X-X′ of FIG. 9;

FIG. 11 is a sectional view of the shower head of FIG. 10;

FIG. 12 is a perspective view of the shower head of FIG. 3, showing the first and second main paths connected to the reflective first and second supply paths and the plurality of first and second diffuse paths;

FIG. 13 shows gas feeding and purging operations applied to form a thin film using the reactor of FIG. 3 while plasma is continuously (RF Plasma-I) or intermittently (RF Plasma-2) generated;

FIG. 14 is a sectional view of a reactor for thin film deposition according to another preferred embodiment of the present invention;

FIG. 15 is a perspective view of a shower head of FIG. 14;

FIG. 16 is a bottom view of the shower head of FIG. 15;

FIG. 17 is a sectional view of the shower head of FIG. 15;

FIG. 18 is a plan view of the section at a height d1 of FIG. 15;

FIG. 19 is a plan view of the section at a height d2 of FIG. 15; and FIG. 20 is a plan view of the section at a height d3 of FIG. 15.

### BEST MODE FOR CARRYING OUT THE INVENTION

Preferred embodiments of a reactor for thin film deposition and a method for depositing a thin film using the reactor according to the present invention will be described in greater detail with reference to the appended drawings.

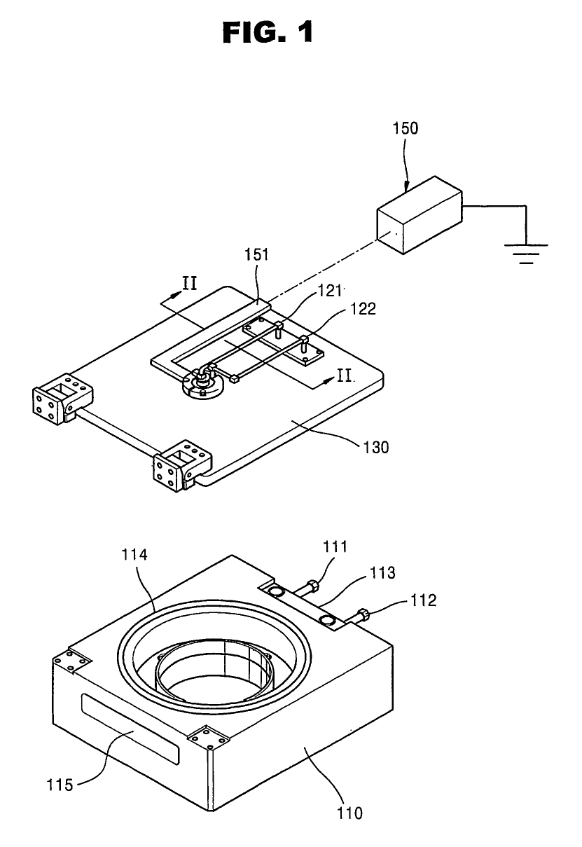

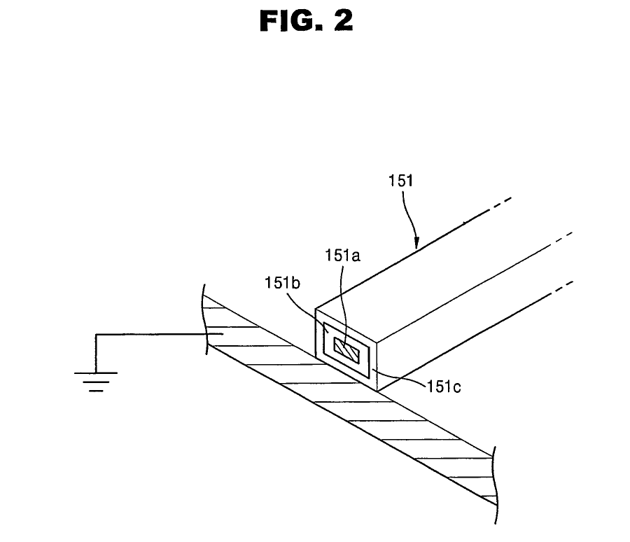

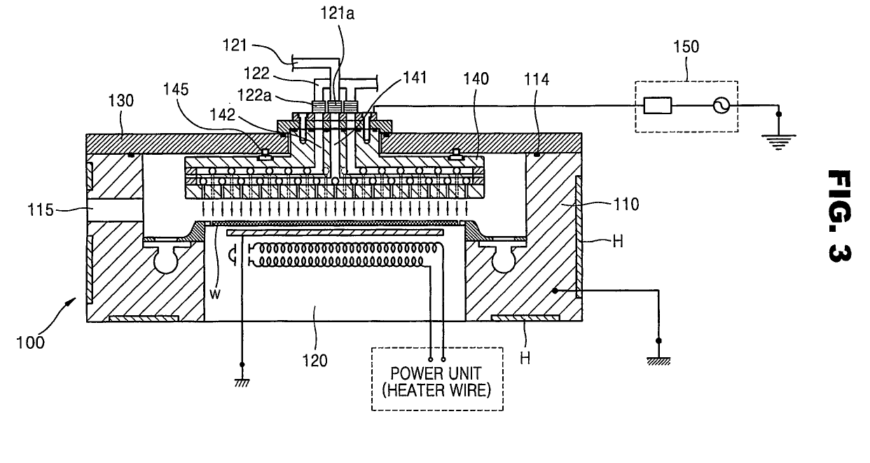

FIG. 1 is an exploded perspective view of a reactor for thin film deposition according to the present invention, and FIG. 2 is a sectional view of a plasma power load of FIG. 1. FIG. 3 is a sectional view of the reactor of FIG. 1 according to a preferred embodiment of the present invention.

Referring to FIG. 1, the reactor for thin film deposition according to the present invention includes a reactor block 110 which receives a wafer w transferred through a wafer transfer slit 115, a wafer block 120 (see FIG. 3) installed in the reactor block 110 to receive the wafer w thereon, a top plate 130 disposed to cover the reactor block 110 and to constantly maintain an inner pressure of the reactor block 110, a shower head 140 (see FIG. 3) which is mounted on the bottom of the top plate 130 and diffuses gases toward the wafer w, an exhaust unit (not shown) which exhausts gases from the reactor block 110, and a plasma generator 150 which generates plasma between the shower head 140 and the wafer block 120.

In the reactor block 110 a first connection pipeline 111 for a first reactant gas and/or an inert gas and a second connection pipeline 112 for a second reactant gas and/or an inert gas are formed. The first and second connection pipelines 111 and 112 are connected to respective first and second supply pipelines 121 and 122 of the shower head 140, which is described later, via a connection unit 113. On the reactor block 110 a main O-ring 114 for tightly sealing the reactor when the reactor block 110 is covered with the top plate 130 is placed.

The plasma generator 150 includes a power road 151 for preventing disturbance due to electromagnetic waves generated from the plasma generator 150 to protect a variety of electronic circuit parts. The power road 151 is connected to the top plate 130 and the shower head 140 and includes a conductive wire 151 electrically connected to the shower head 140, an insulator 151b surrounding the conductive wire 151a, and a grounded conductor 151 surrounding the insulator 151b, as shown in FIG. 2. As the insulator 151b is grounded, electromagnetic waves generated by the plasma generator 150 are absorbed by the grounded conductor 151c through the insulator 151b. As a result, a variety of electronic circuits are prevented from incorrectly operating.

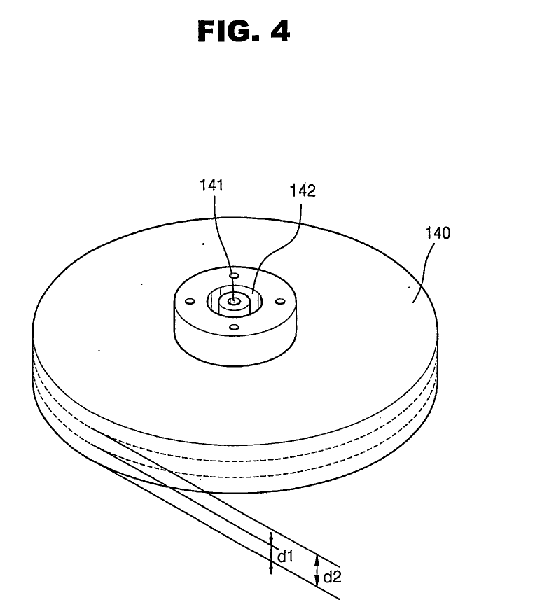

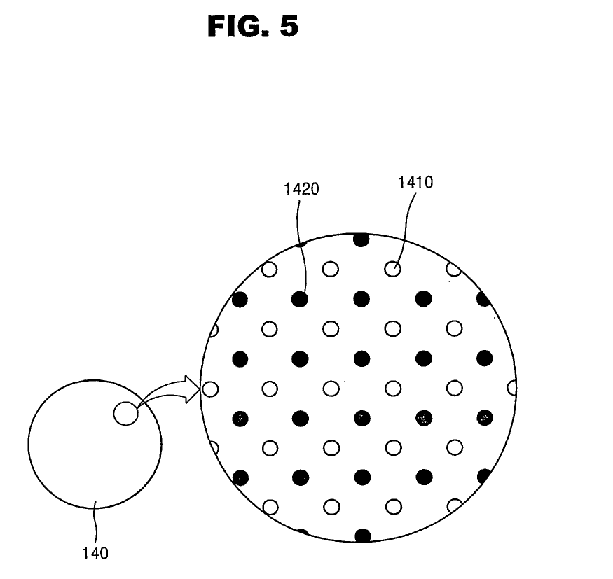

FIG. 3 is a sectional view of the reactor of FIG. 1 according to a preferred embodiment of the present invention. FIG. 4 is a perspective view of the shower head of FIG. 3, and FIG. 5 is a bottom view of the shower head of FIG. 4.

Referring to FIG. 3, in the top plate 130 the first supply pipeline 121 connected to the above-described first connection pipeline 111 to supply the wafer w with the first reactant gas and/inert gas and the second supply pipeline 122 connected to the above-described second connection pipeline 112 to supply the wafer w with the second reactant gas and/or inert gas are mounted.

The shower head 140 for diffusing a reactive gas and/or inert gas toward the wafer w (toward the wafer block 120) is mounted on the bottom of the top plate 130 to be placed in the reactor block 110 when the top plate 130 is covered with the reactor block 110. The shower head 140 is formed of a single body structure, rather than including a plurality of plates coupled to one another by a variety of screws. An insulator 145 is interposed between the shower head 140 and the top plate 130 for insulation.

In the shower head 140 a first supply path 141 connected to the first supply pipeline 121 and a second supply path 142 connected to the second supply pipeline 122 are formed. The first supply pipeline 121 and the first supply path 141 are connected via a first insulating connector 121a, and the second supply pipeline 122 and the second supply path 142 are connected via a second insulating connector 122a. The first and second insulating connectors 121a and 122a prevents an electric signal generated by the plasma generator 150 from being supplied into the first and second supply lines 121 and 122, thereby suppressing unexpected disturbance by the electric signal.

Referring to FIG. 5, in the bottom of the shower head 140, a plurality of first diffuse holes 1410 and a plurality of second diffuse holes 1420 are formed at a constant interval to diffuse gases toward the wafer w.

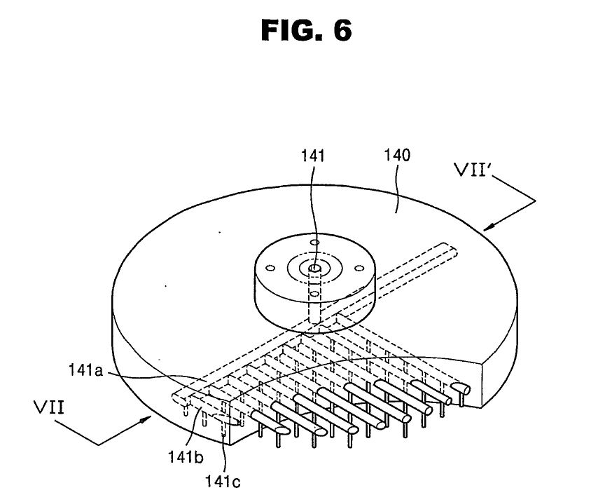

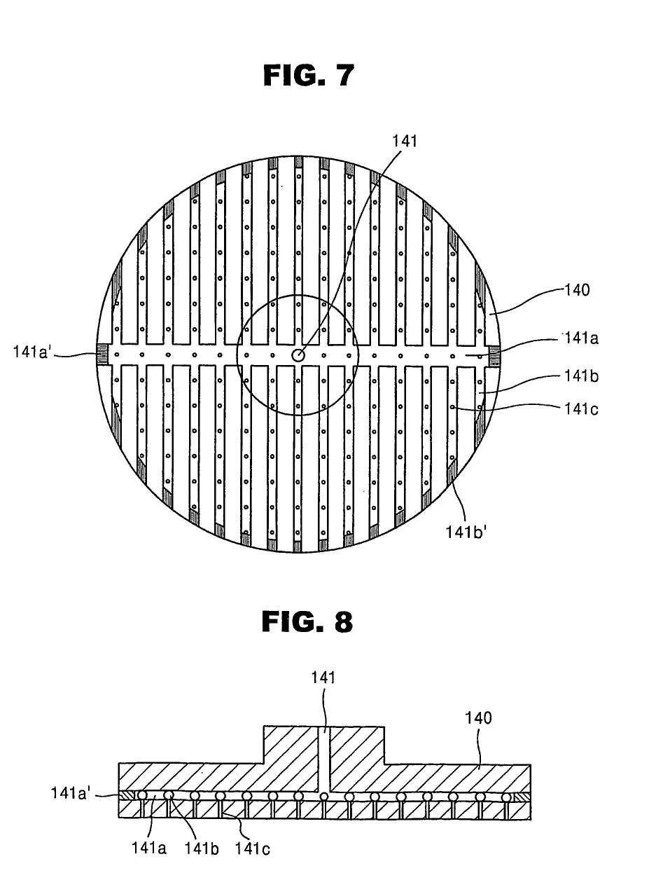

FIG. 6 is a perspective view of the shower head 140 of FIG. 3, showing a first main path connected to the first supply path 141 and a plurality of first diffuse paths. FIG. 7 is a sectional view taken along line VII-VII′ of FIG. 6, and FIG. 8 is a sectional view of the shower head 140 of FIG. 6.

The shower head-140, which is formed as a single body, includes a first main path 141a horizontally extending in connection with the first supply path 141, at a height d1 from the bottom of the shower head 140, as shown in FIG. 4. A plurality of first sub-paths 141b perpendicularly divert from the first main path 141a to be in parallel with the plane of the shower head 140. From each of the first sub-paths 141b a plurality of first diffuse paths 141c extending to the plurality of the first diffuse holes 1410 divert toward the bottom of the shower head 140.

The first main path 141a is implemented by drilling through the side of the shower head 140 with a drilling tool. The first sub-paths 141b are implemented by drilling through the side of the shower head 140 with a drilling tool, to be perpendicular with respect to the first main path 141a. The first diffuse paths 141c are implemented by drilling the bottom of the shower head 140 to a height of the first sub-paths 141b with a drilling tool.

As show in FIG. 7, both ends of the first main path 141a are sealed by press fitting with a predetermined sealing member 141a′, both ends of each of the first sub-paths 141b are sealed by press fitting with another predetermined sealing member 141b′. By doing so, the first main path 141a, the first sub-paths 141b, and the first diffuse paths 141c are formed in the shower head 140.

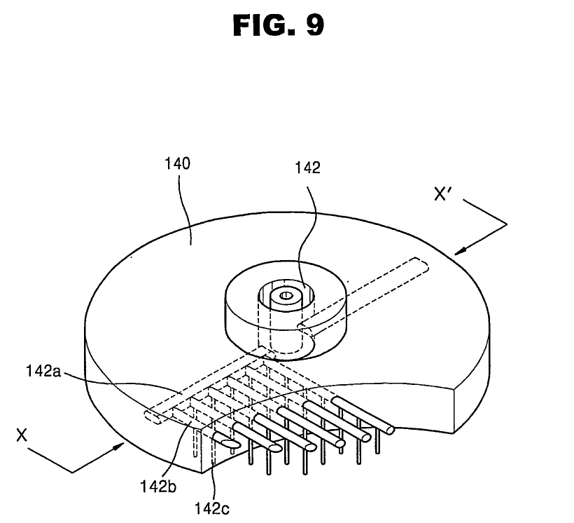

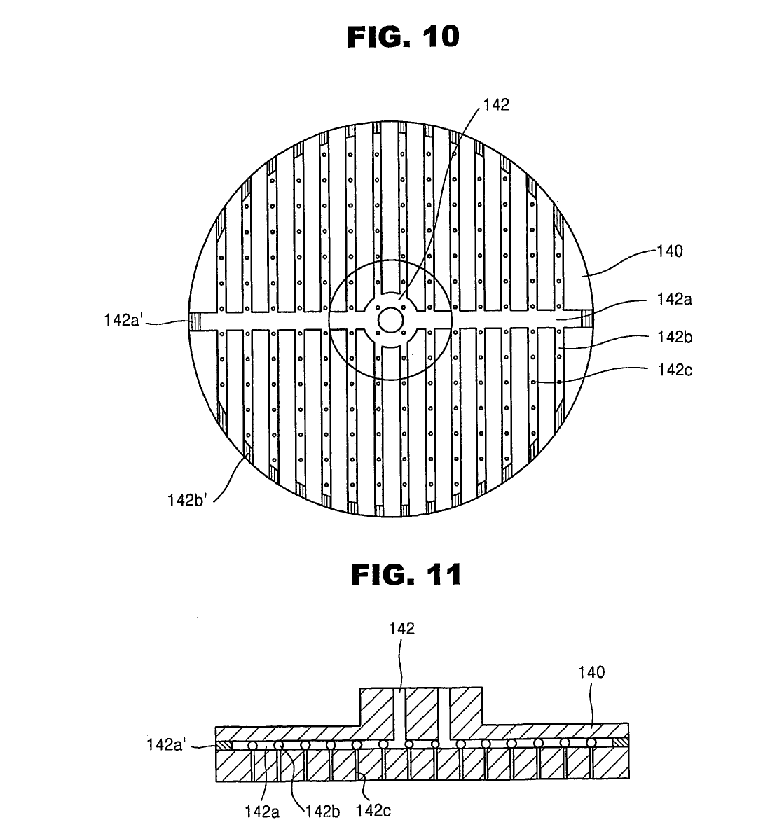

FIG. 9 is a perspective view of the shower head 140 of FIG. 3, showing a second main path connected to the second supply path 142 and a plurality of second diffuse paths. FIG. 10 is a sectional view taken along line X-X′ of FIG. 9, and FIG. 11 is a sectional view of the shower head 140 of FIG. 10.

The shower head 140 includes a second main path 142a horizontally extending in connection with the first supply path 141, at a height d2 from the bottom of the shower head 140, as shown in FIG. 4. A plurality of second sub-paths 142b perpendicularly divert from the second main path 142a to be in parallel with the plane of the shower head 140. From each of the second sub-paths 142b a plurality of second diffuse paths 142c extending to the plurality of the first diffuse holes 1420 divert toward the bottom of the shower head 140.

The second main path 142a is implemented by drilling through the side of the shower head 140 with a drilling tool. The second sub-paths 142b are implemented by drilling through the side of the shower head 140 with a drilling tool, to be perpendicular with respect to the second main path 142a. The second diffuse paths 142c are implemented by drilling the bottom of the shower head 140 to a height of the second sub-paths 142b with a drilling tool.

As shown in FIG. 10, both ends of the second main path 142a are sealed by press fitting with a predetermined sealing member 142a′, both ends of each of the second sub-paths 142b are sealed by press fitting with another predetermined sealing member 142b′. By doing so, the second main path 142a, the second sub-paths 142b, and the second diffuse paths 142c are formed in the shower head 140.

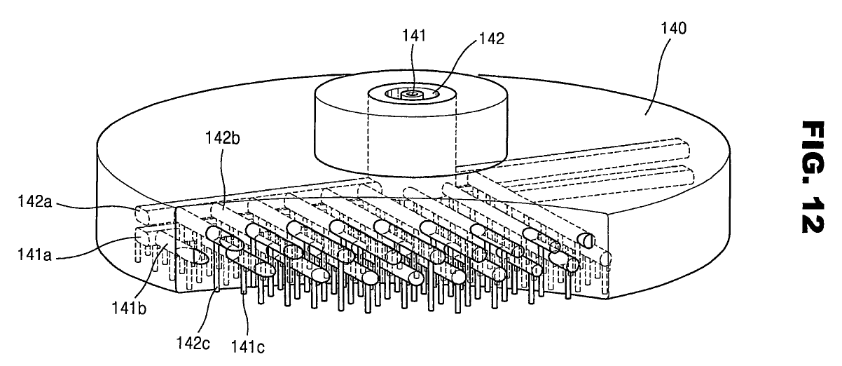

FIG. 12 is a perspective view of the shower head 140 of FIG. 3, showing the first and second main paths 141a and 142a connected to the respective first and second supply paths 141 and 142 and the plurality of first and second diffuse paths 141c and 142c. As shown in FIG. 12, the first main path 141a and the second main path 142a are formed at different heights in the shower head 140 and are sealed by press fitting with predetermined sealing members, thereby completing formation of the single-body shower head.

Although in the above embodiment the first and second main paths are formed parallel to each other, it will be appreciated that the first and second main paths could be formed perpendicular to each other without limitation to the above structure.

Hereinafter, a method for depositing a thin film using the reactor described in the above embodiment will be described.

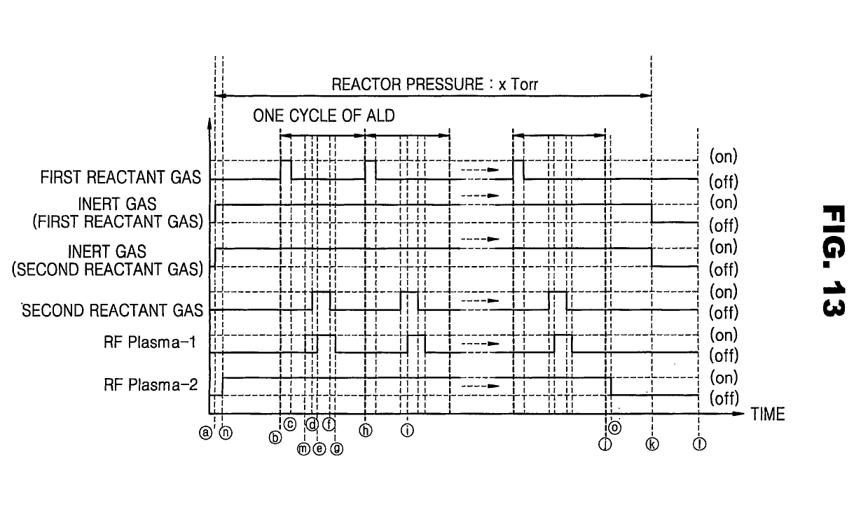

FIG. 13 shows gas feeding and purging operations applied to form a thin film using the reactor of FIG. 3 while plasma is continuously (RF Plasma-I) or intermittently (RF Plasma-2) generated.

1) When plasma is intermittently generated (RF Plasma-I)

In FIG. 13, the X-axis denotes time, and the Y-axis indicates the cycles of applying first and second reactant gases and inert gases and generating plasma.

During the period of depositing a thin film, i.e., from the periods \mathring{a}-\mathring{k}, inert gases are sprayed through the first and second diffuse holes 1410 and 1420 toward the wafer w while the reactor 100 is maintained at a predetermined pressure of x Torr.

In the pre-heating period of \mathring{a}-\mathring{h}, the wafer w is loaded onto the wafer block 120 and pre-heated for stabilization to an appropriate temperature for thin film formation without feeding the first and second reactant gases into the reactor 100. If a reactant gas is diffused prior to the period of \mathring{b}, the thin film is deposited at a temperature lower than the appropriate temperature so that the resulting thin film (hereinafter, ALD thin film) having a thickness of atomic layers may have poor purity and properties.

The period of \mathring{b}-\mathring{h} corresponding to one cycle of ALD to form a single ALD layer are divided into four sub-periods: a first sub-period of \mathring{b}-\mathring{c} for feeding the first reactant gas, a second sub-period of \mathring{c}-\mathring{d} for purging the first reactant gas, a third sub-period of \mathring{d}-\mathring{f} for feeding the second reactant gas, and a fourth step of \mathring{f}-\mathring{h} for purging the second reactant gas. In particular, in the first sub-period of \mathring{b}-\mathring{c}, the first reactant gas is fed through the first diffuse holes 1410 into the reactor 100 over the wafer w in a predetermined amount, and in the second sub-period of \mathring{c}-\mathring{d}, the fed first reactant gas is purged from the reactor 100. In the third sub-period of \mathring{d}-\mathring{f}, the second reactant gas is fed through the second diffuse holes 1420 into the reactor 100 over the wafer w in a predetermined amount, and in the fourth sub-period of \mathring{f}-\mathring{h}, the fed second reactant gas is purged from the reactor 100. Through the four sub-periods at least one ALD thin film is formed. By repeating this cycle, for example, to the period of \mathring{j}, a thin film of a desired thickness can be deposited.

During the ALD, plasma is generated in the reactor 100, and more specifically, between the wafer block 120 and the shower head 140, at least one cycle for each cycle of the ALD. The cyclic generation of radio frequency (RF) plasma is achieved by turning on/off an RF generator (not shown) of the plasma generator 150 and transmitting the RF into the reactor 100 via an RF matching box (not shown). Here, the point of time at which the RF plasma is generated (“on”) is during the purging of the first reactant gas, for example, in the period of \mathring{m}, or immediately after initiation of the feeding of the second reactant gas, for example, after the period of \mathring{e}. Next, the generation of the RF plasma is stopped (“off”) during the purging of the second reactant gas, for example, in the period of \mathring{g}. The reason for continuing the generation of the plasma even after initiation of the purging of the second reactant gas is to maximize the consumption of the second reaction gas used to form a thin film on the wafer w. The pulsed generation of the plasma is continued until the period of \mathring{j}. In the period of \mathring{j}-\mathring{k}, the diffusion of the first and second reactant gases is stopped whereas inert gases are supplied into the reactor 100 to rapidly exhaust the remaining reactant gases from the reactor 100.

In the period of \mathring{k}-\mathring{l}, the flow of all of the gases into the reactor 100 is stopped as a step preceding a transfer of the wafer to a transfer module (not shown) and performed to protect the transfer module from being contaminated by the reactant gases remaining in the reactor 100 when a vat valve is opened to separate the transfer module from the reactor 100.

2) When plasma is continuously generated (RF Plasma-II)

In FIG. 13, the X-axis denotes time, and the Y-axis indicates the cycles of applying first and second reactant gases and inert gases and generating plasma.

During the period of depositing a thin film, i.e., from the periods \mathring{a}-\mathring{k}, inert gases are sprayed through the first and second diffuse holes 1410 and 1420 toward the wafer w while the reactor 100 is maintained at a predetermined pressure of x Torr.

In the pre-heating period of \mathring{a}-\mathring{b}, the wafer w is loaded onto the wafer block 120 and pre-heated for stabilization to an appropriate temperature for thin film formation without feeding the first and second reactant gases into the reactor 100. If a reactant gas is diffused prior to the period of \mathring{b}, the thin film is deposited at a temperature lower than the appropriate temperature so that the resulting ALD thin film may have poor purity and properties.

The period of \mathring{b}-\mathring{h} corresponding to one cycle of ALD to form a single ALD layer are divided into four sub-periods: a first sub-period of \mathring{b}-\mathring{c} for feeding the first reactant gas, a second sub-period of \mathring{c}-\mathring{d} for purging the first reactant gas, a third sub-period of \mathring{d}-\mathring{f} for feeding the second reactant gas, and a fourth step of \mathring{f}-\mathring{h} for purging the second reactant gas. In particular, in the first sub-period of \mathring{b}-\mathring{c}, the first reactant gas is fed through the first diffuse holes 1410 into the reactor 100 over the wafer w in a predetermined amount, and in the second sub-period of \mathring{c}-\mathring{d}, the fed first reactant gas is purged from the reactor 100. In the third sub-period of \mathring{f}-\mathring{h}, the second reactant gas is fed through the second diffuse holes 1420 into the reactor 100 over the wafer w in a predetermined amount, and in the fourth sub-period of \mathring{f}-\mathring{h}, the fed second reactant gas is purged from the reactor 100. Through the four sub-periods at least one ALD thin film is formed. By repeating this cycle, for example, to the period of \mathring{j}, a thin film of a desired thickness can be deposited.

During the ALD, plasma is generated (“on”) in the reactor 100 through all of the ALD cycles by the plasma generator 150. Here, the point of time at which the RF plasma is generated is immediately after the supply of the inert gases into the reactor 100, for example, after the period of \mathring{n}. The point of time at which the generation of the RF plasma is stopped (“off”) is immediately after completion of all of the ALD cycles, for example, after the period of \mathring{o}.

A second embodiment of the reactor for thin film deposition according to the present invention will be described.

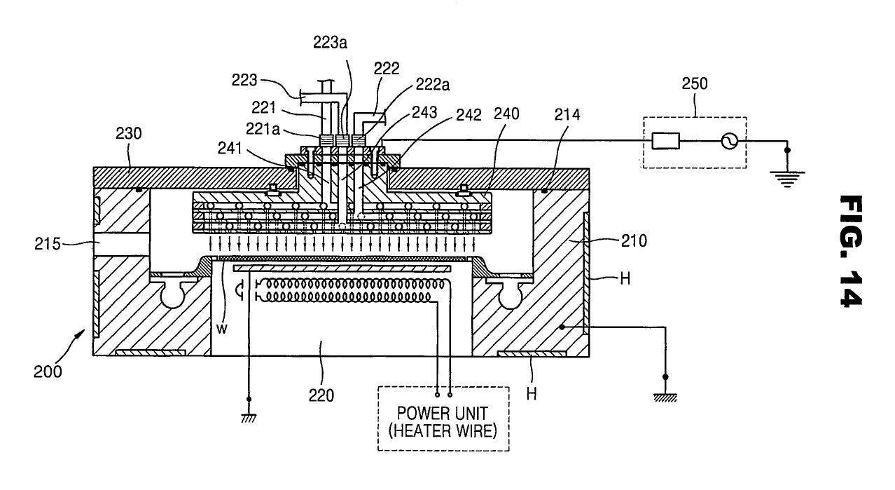

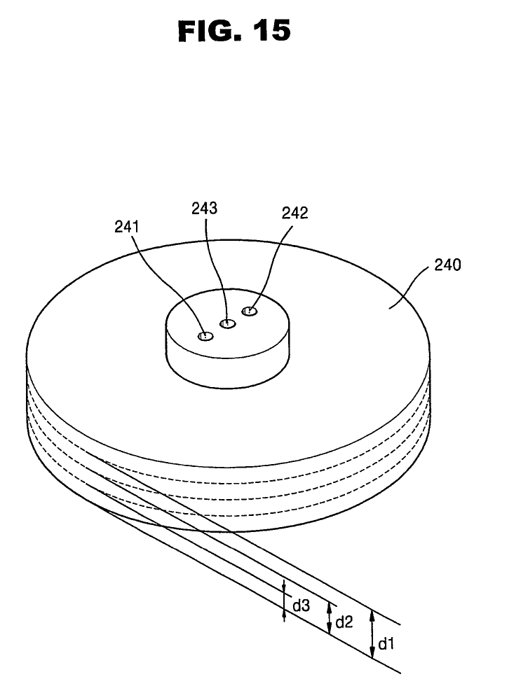

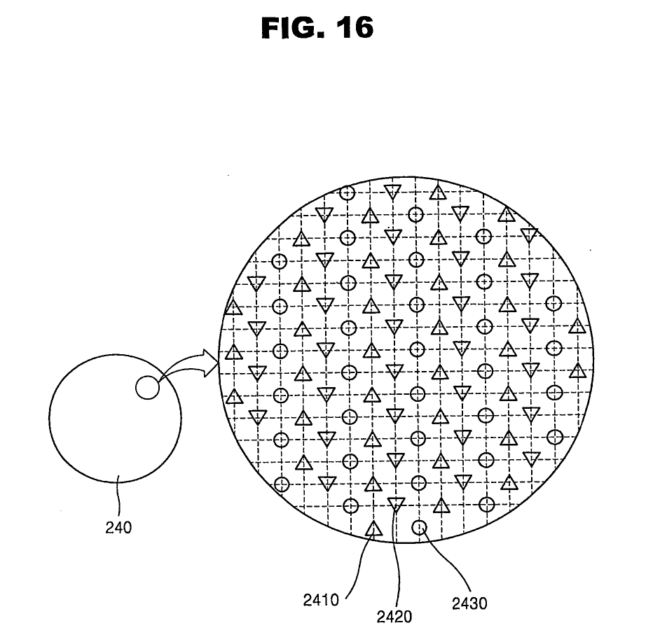

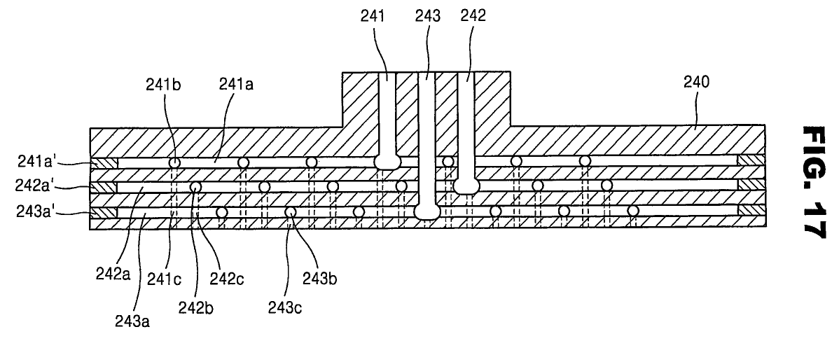

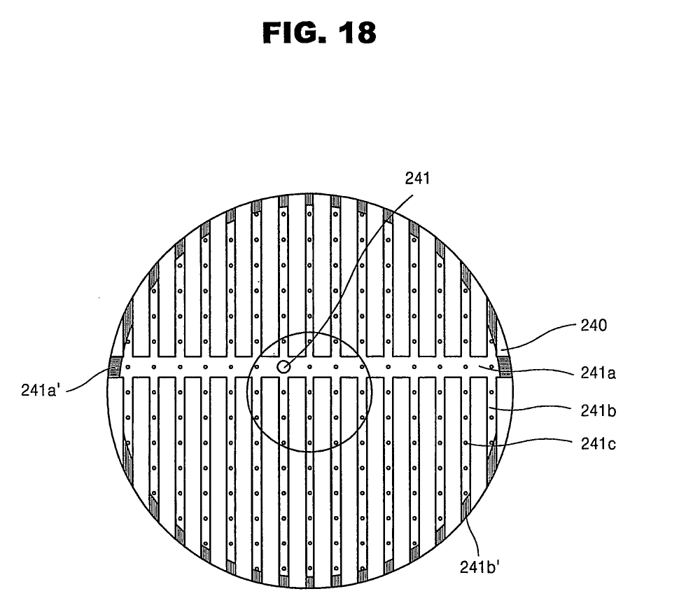

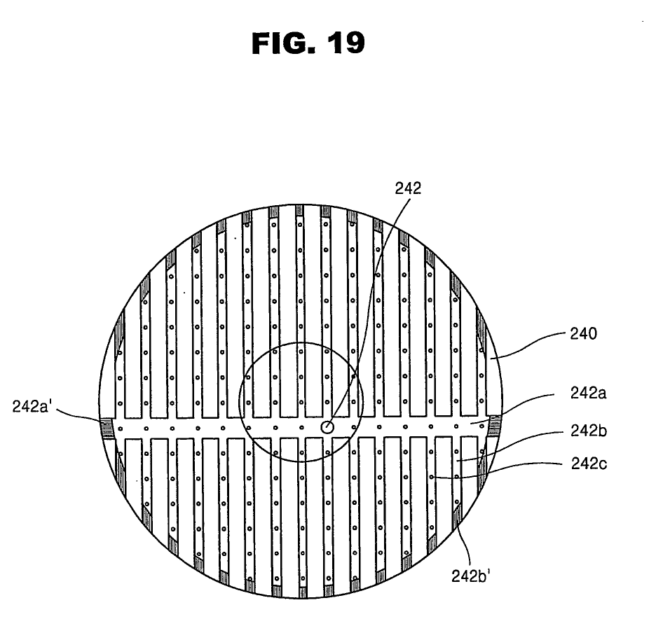

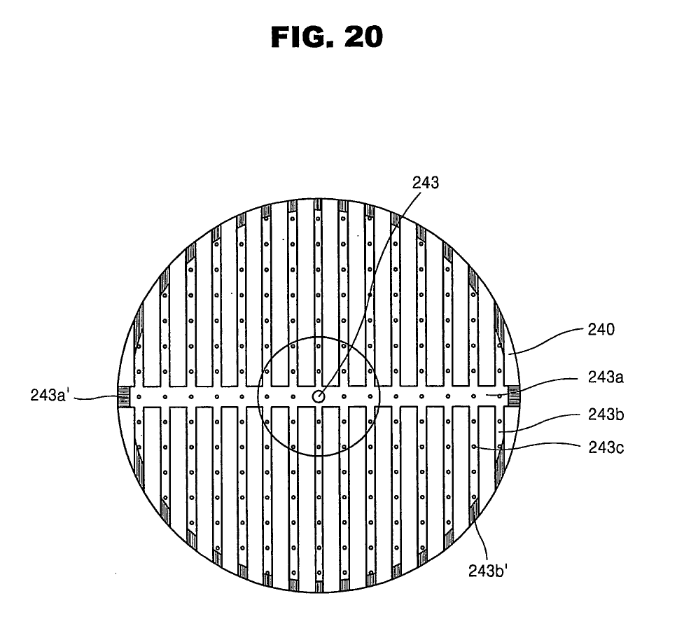

FIG. 14 is a sectional view of the reactor for thin film deposition according to another preferred embodiment of the present invention. FIG. 15 is a perspective view of a shower head of FIG. 14, FIG. 16 is a bottom view of the shower head of FIG. 15, FIG. 17 is a sectional view of the shower head of FIG. 15, FIG. 18 is a plan view of the section at a height d1 of FIG. 15, FIG. 19 is a plan view of the section at a height d2 of FIG. 15, and FIG. 20 is a plan view of the section at a height d3 of FIG. 15.

Referring to FIG. 14, the reactor for thin film deposition according to the second embodiment of the present invention includes a reactor block 210 which receives a wafer w transferred through a wafer transfer slit 215, a wafer block 220 installed in the reactor block 210 to receive the wafer w thereon, a top plate 130 disposed to cover the reactor block 210 and to constantly maintain an inner pressure of the reactor block 210, a shower head 240 which is mounted on the bottom of the top plate w30 and diffuses gases toward the wafer w, an exhaust unit (not shown) which exhausts gases from the reactor block 210, and a plasma generator 250 which generates plasma between the shower head 240 and the wafer block 220. The plasma generator 250 is the same as the plasma generator 150 described in the first embodiment with reference to FIG. 3, and thus a detailed description of the plasma generator 250 will be omitted.

In the top plate 230 and the shower head 240, a first supply pipeline 221 for supplying a first reactant gas and/or inert gas toward the wafer w, a second supply pipeline 222 for supplying a second reactant gas and/or inert gas toward the wafer w, and a third supply pipeline 223 for supplying a third reactant gas and/or inert gas toward the wafer w are mounted.

The shower head 240 coupled to the bottom of the top plate 230 is formed as a single body. In the shower head 240 a first supply path 241 connected to the first supply pipeline 221, a second supply path 242 connected to the second supply pipeline 222, and a third supply path 243 connected to a third supply pipeline 223 are formed. The first supply pipeline 221 and the first supply path 241 are connected via a first insulating connector 221a, the second supply pipeline 222 and the second supply path 242 are connected via a second insulating connector 222a, and the third supply pipeline 223 and the third supply path 243 are connected via a third insulating connector 223.

Referring to FIG. 16, in the bottom of the shower head 240, a plurality of first diffuse holes 2410, a plurality of second diffuse holes 2420, and a plurality of third diffuse holes 2430 are formed at a constant interval to diffuse gases toward the wafer w.

Referring to FIGS. 15, 17, and 18, the shower head 240 includes a first main path 241a horizontally extending in connection with the first supply path 241, at a height d1 from the bottom of the shower head 240. A plurality of first sub-paths 241b perpendicularly divert from the first main path 241a to be in parallel with the plane of the shower head 240. From each of the first sub-paths 241b a plurality of first diffuse paths 241c extending to the plurality of the first diffuse holes 2410 divert toward the bottom of the shower head 240.

Referring to FIGS. 15, 17, and 19, the shower head 240 includes a second main path 242a horizontally extending in connection with the second supply path 242, at a height d2 from the bottom of the shower head 240. A plurality of second sub-paths 242b perpendicularly divert from the second main path 242a to be in parallel with the plane of the shower head 240. From each of the second sub-paths 242b a plurality of second diffuse paths 242c extending to the plurality of the second diffuse holes 2420 divert toward the bottom of the shower head 240.

Referring to FIGS. 15, 17, and 20, the shower head 240 includes a third main path 243a horizontally extending in connection with the third supply path 242, at a height d3 from the bottom of the shower head 240. A plurality of third sub-paths is 243b perpendicularly divert from the third main path 243a to be in parallel with the plane of the shower head 240. From each of the third sub-paths 243b a plurality of third diffuse paths 243c extending to the plurality of the third diffuse holes 2420 divert toward the bottom of the shower head 240.

Both ends of each of the first, second, and third main paths 241a, 242a, and 243a are sealed by press fitting with predetermined sealing members 241a′, 242b′, and 243c′, respectively, and both ends of each of the first, second, and third sub-paths 241b, 242b, and 243b are sealed by press fitting with another predetermined sealing members 241b′, 242b′, and 243b′, respectively. By doing so, the first, second, and third main paths 241a, 242a, and 243a, the first, second, and third sub-paths 241b, 242b, and 243b, and the first, second, and third diffuse paths 241c, 242c, and 243c are formed in the shower head 240.

The first, second, and third main paths 241a, 242a, and 243a are implemented by drilling at different heights through the side of the shower head 240 with a drilling tool. The first, second, and third sub-paths 241b, 242b, and 243b are implemented by drilling through the side of the shower head 240 with a drilling tool, to be perpendicular with respect to the first, second, and third main paths 241a, 242a, and 243a, respectively. The first, second, and third diffuse paths 241c, 242c, and 243c are implemented by drilling the bottom of the shower head 240 to a height of the respective first, second, and third sub-paths 241b, 242b, and 243b with a drilling tool.

Although in the above second embodiment the first, second, and third main paths 241a, 242a, and 243a are formed parallel to each other, it will be appreciated that at least two of the first, second, and third main paths 241a, 242a, and 243a could be formed parallel or perpendicular to each other without limitation to the above structure.

Hereinafter, a method for depositing a thin film using the reactor according to the second embodiment of the present invention will be described.

The thin film deposition method using the reactor according to the second embodiment of the present invention is similar to that using the reactor according to the first embodiment of the preferred embodiment. In particular, inert gases are continuously supplied over the wafer w through the first, second, and third diffuse holes 2410, 2420, and 2430. A first reactant gas is fed through the first diffuse holes 2410 into the reactor in a predetermined amount and purged. Next, a second reactant gas is fed through the second diffuse holes 2420 into the reactor in a predetermined amount and purged, and a third reactant gas is fed through the third diffuse holes 2430 into the reactor in a predetermined amount and purged. This one cycle of ALD is repeated. Here, plasma is generated between the shower head 240 and the wafer block 220 after feeding each of the second and third reactant gases, and the generation of the plasma is stopped after purging each of the second and third reaction gases and before feeding of a next reactant gas.

Alternatively, the inert gases are continuously supplied over the wafer w through the first, second, and third diffuse holes 2410, 2420, and 2430. The first reactant gas is fed through the first diffuse holes 2410 into the reactor in a predetermined amount and purged. Next, the second reactant gas is fed through the second diffuse holes 2420 into the reactor in a predetermined amount and purged, and the third reactant gas is fed through the third diffuse holes 2430 into the reactor in a predetermined amount and purged. This one cycle of ALD is repeated. Here, plasma is continuously generated between the shower head 240 and the wafer block 220 while the first, second, and third reactant gases are fed into and purged from the reactor.

As described above, a reactor for thin film deposition according to the present invention includes a shower head formed as a single body. As a result, when a thin film is deposited using a plurality of reactant gases, a high-purity thin film that has good electrical properties and step coverage can be effectively deposited on a wafer.

In addition, two or more reactant source gases can be uniformly sprayed over the wafer to deposit an ALD thin film. By intermittently or continuously applying plasma between the shower head and the wafer block while the reactant gases are periodically fed and purged, a high-purity thin film can be effectively formed at a lower temperature than using conventional ALD or CVD.

1. In a reactor for thin film deposition, comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate and diffuses gas toward the wafer; and an exhaust unit which exhausts the gas from the reactor block, the reactor characterized by comprising:
a first supply pipeline which supplies a first reactant gas and/or an inert gas to the wafer; and
a second supply pipeline which supplies a second reactant gas and/or an inert gas to the wafer,
wherein the shower head comprises:
a first supply path connected to the first supply pipeline;
a plurality of first diffuse holes formed in the bottom of the shower head at a constant interval;
a first main path formed parallel to the plane of the shower head and connecting the plurality of first diffuse holes and the first supply path;
a second supply path connected to the second supply pipeline;
a plurality of second diffuse holes formed in the bottom of the shower head at a constant interval as the plurality of the first diffuse holes; and
a second main path formed parallel to the plane of the shower head at a different height from the first main path and connecting the plurality of second diffuse holes and the second supply path.

2. The reactor of claim 1 or 2, wherein the first main path and the second main path are formed parallel or perpendicular to each other.

3. The reactor of claim 1, wherein the shower head further comprises a plurality of first sub-paths perpendicularly diverting from the first main path to be in parallel with the plane of the shower head and a plurality of first diffuse paths connecting the plurality of first sub-paths and the plurality of first diffuse holes.

4. The reactor of claim 1, wherein the shower head further comprises a plurality of second sub-paths perpendicularly diverting from the second main path to be in parallel with the plane of the shower head and a plurality of second diffuse paths connecting the plurality of second sub-paths and the plurality of second diffuse holes.

5. The reactor of claim 1, further comprising:
a plasma generator which generates plasma between the wafer block and the shower head; and
a power road for preventing disturbance due to electromagnetic waves generated from the plasma generator, including a conductive wire electrically connected to the shower head, an insulator surrounding the conductive wire, and a grounded conductor surrounding the insulator.

6. The reactor of claim 1, wherein the first supply pipeline and the first supply path are connected via a first insulating connector, and the second supply pipeline and the second supply path are connected via a second insulating connector.

7. In a reactor for thin film deposition, comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate and diffuses gas toward the wafer; and an exhaust unit which exhausts the gas from the reactor block, the reactor characterized by comprising:
a first supply pipeline which supplies a first reactant gas and/or an inert gas to the wafer;
a second supply pipeline which supplies a second reactant gas and/or an inert gas to the wafer; and
a third supply pipeline which supplies a third reactant gas and/or an inert gas to the wafer,
wherein the shower head comprises:
a first supply path connected to the first supply pipeline;
a plurality of first diffuse holes formed in the bottom of the shower head at a constant interval;
a first main path formed parallel to the plane of the shower head and connecting the plurality of first diffuse holes and the first supply path;
a second supply path connected to the second supply pipeline;
a plurality of second diffuse holes formed in the bottom of the shower head at a constant interval as the plurality of the first diffuse holes;
a second main path formed parallel to the plane of the shower head at a different height from the first main path and connecting the plurality of second diffuse holes and the second supply path;
a third supply path connected to the third supply pipeline;
a plurality of third diffuse holes formed in the bottom of the shower head at a constant interval as the plurality of the first and second diffuse holes; and
a third main path formed parallel to the plane of the shower head at a different height from the first and second main paths and connecting the plurality of third diffuse holes and the third supply path.

8. The reactor of claim 7, wherein at least two of the first, second, and third main paths are formed parallel or perpendicular to each other.

9. The reactor of claim 7, wherein the shower head further comprises a plurality of first sub-paths perpendicularly diverting from the first main path to be in parallel with the plane of the shower head and a plurality of first diffuse paths connecting the plurality of first sub-paths and the plurality of first diffuse holes.

10. The reactor of claim 7, wherein the shower head further comprises a plurality of second sub-paths perpendicularly diverting from the second main path to be in parallel with the plane of the shower head and a plurality of second diffuse paths connecting the plurality of second sub-paths and the plurality of second diffuse holes.

11. The reactor of claim 7, wherein the shower head further comprises a plurality of third sub-paths perpendicularly diverting from the third main path to be in parallel with the plane of the shower head and a plurality of third diffuse paths connecting the plurality of third sub-paths and the plurality of third diffuse holes.

12. The reactor of claim 7, further comprising:
a plasma generator which generates plasma between the wafer block and the shower head; and
a power road for preventing disturbance due to electromagnetic waves generated from the plasma generator, including a conductive wire electrically connected to the shower head, an insulator surrounding the conductive wire, and a grounded conductor surrounding the insulator.

13. The reactor of claim 7, wherein the first supply pipeline and the first supply path are connected via a first insulating connector, the second supply pipeline and the second supply path are connected via a second insulating connector, and the third supply pipeline and the third supply path are connected via a third insulating connector.

14. A method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer and a plurality of second diffuse holes for supplying a second reactant gas and/or an inert gas to the wafer; a plasma generator which generates plasma between the wafer block and the shower head; and an exhaust unit which exhausts the gas from the reactor block, the method comprising:
while the inert gases are continuously supplied to the wafer through the plurality of first and second diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, and purging the second reactant gas from the reactor; and
generating the plasma after feeding the second reactant gas and stopping the generation of the plasma after pursing the second reactant gas and before feeding the first reactant gas.

15. A method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer and a plurality of second diffuse holes for supplying a second reactant gas and/or an inert gas to the wafer; a plasma generator which generates plasma between the wafer block and the shower head; and an exhaust unit which exhausts the gas from the reactor block, the method comprising:
while the inert gases are continuously supplied to the wafer through the plurality of first and second diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, and purging the second reactant gas from the reactor; and
continuously generating the plasma during the feeding and purging of the first and second reactant gases.

16. A method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer, a plurality of second diffuse holes for supplying a second reactant gas and/or an inert gas to the wafer, and a plurality of third diffuse holes for supplying a third reactant gas and/or an inert gas to the wafer; a plasma generator which generates plasma between the wafer block and the shower head; and an exhaust unit which exhausts the gas from the reactor block, the method comprising:
while the inert gases are continuously supplied to the wafer through the plurality of first, second, and third diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, purging the second reactant gas from the reactor, feeding the third reactant gas into the reactor through the plurality of third diffuse holes in a predetermined amount, and purging the third reactant gas from the reactor; and
generating the plasma after feeding each of the second and third reactant gases and stopping the generation of the plasma after purging each of the second and third reactant gases and before feeding a next reactant gas.

17. A method for depositing a thin film using a reactor comprising: a reactor block which receives a wafer transferred through a wafer transfer slit; a wafer block which is installed in the reactor block to receive the wafer thereon; a top plate disposed to cover the reactor block; a shower head which is mounted on the bottom of the top plate, diffuses gas toward the wafer, and includes a plurality of first diffuse holes for supplying a first reactant gas and/or an inert gas to the wafer, a plurality of second diffuse holes for supplying a second reactant gas and/or an inert gas to the wafer, and a plurality of third diffuse holes for supplying a third reactant gas and/or an inert gas to the wafer; a plasma generator which generates plasma between the wafer block and the shower head; and an exhaust unit which exhausts the gas from the reactor block, the method comprising:
while the inert gases are continuously supplied to the wafer through the plurality of first, second, and third diffuse holes, repeating a cycle of feeding the first reactant gas into the reactor through the plurality of first diffuse holes in a predetermined amount, purging the first reactant gas from the reactor, feeding the second reactant gas into the reactor through the plurality of second diffuse holes in a predetermined amount, purging the second reactant gas from the reactor, feeding the third reactant gas into the reactor through the plurality of third diffuse holes in a predetermined amount, and purging the third reactant gas from the reactor; and continuously generating the plasma during the feeding and purging of the first, second, and third reactant gases.

18. The reactor of claim 2, wherein the shower head further comprises a plurality of first sub-paths perpendicularly diverting from the first main path to be in parallel with the plane of the shower head and a plurality of first diffuse paths connecting the plurality of first sub-paths and the plurality of first diffuse holes.

19. The reactor of claim 2, wherein the shower head further comprises a plurality of second sub-paths perpendicularly diverting from the second main path to be in parallel with the plane of the shower head and a plurality of second diffuse paths connecting the plurality of second sub-paths and the plurality of second diffuse holes.

20. The reactor of claim 2, further comprising:
a plasma generator which generates plasma between the wafer block and the shower head; and
a power road for preventing disturbance due to electromagnetic waves generated from the plasma generator, including a conductive wire electrically connected to the shower head, an insulator surrounding the conductive wire, and a grounded conductor surrounding the insulator.

21. The reactor of claim 2, wherein the first supply pipeline and the first supply path are connected via a first insulating connector, and the second supply pipeline and the second supply path are connected via a second insulating connector.

22. The reactor of claim 8, wherein the shower head further comprises a plurality of first sub-paths perpendicularly diverting from the first main path to be in parallel with the plane of the shower head and a plurality of first diffuse paths connecting the plurality of first sub-paths and the plurality of first diffuse holes.

23. The reactor of claim 8, wherein the shower head further comprises a plurality of second sub-paths perpendicularly diverting from the second main path to be in parallel with the plane of the shower head and a plurality of second diffuse paths connecting the plurality of second sub-paths and the plurality of second diffuse holes.

24. The reactor of claim 8, wherein the shower head further comprises a plurality of third sub-paths perpendicularly diverting from the third main path to be in parallel with the plane of the shower head and a plurality of third diffuse paths connecting the plurality of third sub-paths and the plurality of third diffuse holes.

25. The reactor of claim 8, further comprising:
a plasma generator which generates plasma between the wafer block and the shower head; and
a power road for preventing disturbance due to electromagnetic waves generated from the plasma generator, including a conductive wire electrically connected to the shower head, an insulator surrounding the conductive wire, and a grounded conductor surrounding the insulator.

26. The reactor of claim 8, wherein the first supply pipeline and the first supply path are connected via a first insulating connector, the second supply pipeline and the second supply path are connected via a second insulating connector, and the third supply pipeline and the third supply path are connected via a third insulating connector.
